(19) United States
(12) Patent Application Publication
(10) Pub. No.: US 2011/0084334 A1
(43) Pub. Date: Apr. 14, 2011

(54) BILATERAL CONDUCTION SEMICONDUCTOR DEVICE AND MANUFACTURING METHOD THEREOF

(76) Inventors: Wei-Chieh Lin, Hsinchu City (TW); Jen-Hao Yeh, Kaohsiung County (TW); Jia-Fu Lin, Yilan County (TW); Chia-Hui Chen, Taichung County (TW)

(21) Appl. No.: 12/615,271

(22) Filed: Nov. 10, 2009

(30) Foreign Application Priority Data
Oct. 14, 2009 (TW) 098134751

(51) Int. Cl. H01L 29/78; H01L 21/336

(52) U.S. Cl. 257/331; 438/270; 257/E29.262; 257/E21.41

(57) ABSTRACT

A bilateral conduction semiconductor device and a manufacturing method thereof are provided. The bilateral conduction semiconductor device includes an epitaxial layer having a first conductive type and a first trench, a first gate conductive layer disposed on a sidewall of the first trench, a second gate conductive layer disposed opposite to the first gate conductive layer, and a doped region having the first conductive type. The doped region is disposed in the epitaxial layer between the first gate conductive layer and the second gate conductive layer, and a doped concentration of the doped region is larger than a doped concentration of the epitaxial layer.

### BACKGROUND OF THE INVENTION

1. Field of the Invention

The present invention relates to a bilateral conduction semiconductor device and a manufacturing method thereof, and more particularly to a bilateral conduction semiconductor device having a lower on-resistance and a manufacturing method thereof.

2. Description of the Prior Art

A conventional bilateral conduction semiconductor device is disposed in a battery and is utilized to protect the battery from being damaged in a charging and discharging process. In order to have capability to protect the battery, the conventional bilateral conduction semiconductor device may be formed by two N-type power metal oxide semiconductor field effect transistors (MOSFETs), and drain electrodes of N-type power MOSFETs are electrically connected to each other. Each N-type power MOSFET includes a MOSFET and a PN diode, wherein a P-type region of the PN diode is electrically connected to a source electrode of the MOSFET, and an N-type region of the PN diode is electrically connected to a drain electrode of the MOSFET.

Please refer to FIG. 1. FIG. 1 is a cross-sectional diagram illustrating a conventional N-type power MOSFET according to the prior art. As shown in FIG. 1, the conventional N-type power MOSFET 10 includes an N-type substrate 12, and an N-type epitaxial layer 14 which is disposed on the N-type substrate 12. Two P-type doped base regions 16 are disposed on the N-type epitaxial layer 14, two N-type source regions 18 are disposed in the P-type doped base regions 16 to serve as source electrodes, and a source metal layer 20 covering the N-type substrate 12 is electrically connected to each N-type source region 18. A gate insulating layer 22 and a gate conductive layer 24 disposed in the gate insulating layer 22 are disposed between two N-type source regions 18 and between the source metal layer 20 and the N-type substrate 12. Also, a drain metal layer 26 is disposed under the N-type substrate 12.

In addition, please refer to FIG. 2. FIG. 2 is a schematic diagram illustrating a conventional bilateral conduction semiconductor device according to the prior art. As shown in FIG. 2, two N-type power MOSFETs 10a and 10b included in the conventional bilateral conduction semiconductor device 50 are disposed at two sides of an insulating layer 28, so that the insulating layer 28 electrically isolates the N-type power MOSFET 10a and the N-type power MOSFET 10b. Also, two N-type power MOSFETs 10a and 10b share the same drain metal layer 26, so that drain electrodes of two N-type power MOSFETs 10a and 10b are electrically connected to each other. When the conventional bilateral conduction semiconductor device 50 is in the on-state, electrical current will flow from a source metal layer 18a of the N-type power MOSFET 10a to a source metal layer 18b of the N-type power MOSFET 10b, as illustrated by arrows of FIG. 2.

However, an insulating layer is required to isolate each N-type power MOSFET in the conventional bilateral conduction semiconductor device. Therefore, a distance is between one source electrode of the N-type power MOSFET and one source electrode of the other N-type power MOSFET. When the conventional bilateral conduction semiconductor device 50 is in the on-state, current easily flows from the source electrode of the N-type power MOSFET downward through an N-type epitaxial layer and a drain metal layer of the same N-type power MOSFET. Then, the current flows through the drain metal layer and laterally transmits to the drain metal layer of another N-type power MOSFET. Subsequently, the electrical current is upward through the N-type epitaxial layer and transmits to the source electrode of another N-type power MOSFET. Also, a percentage of the on-resistance of the N-type epitaxial layer to the on-resistance of the bilateral conduction semiconductor device is substantially 30%, and the percentage is higher when the on-state voltage is higher. For this reason, the on-resistance is limited by the resistance of the N-type epitaxial layer, so that the charging and discharging current can not be increased due to the limitation of the on-resistance, and thus the efficiency of the charging and discharging decreases.

### SUMMARY OF THE INVENTION

It is therefore one of the objectives of the present invention to provide a bilateral conduction semiconductor device and a manufacturing method thereof to decrease the on-resistance and thus increase the charging or discharging current.

According to the present invention, a bilateral conduction semiconductor device is provided. The bilateral conduction semiconductor device includes a substrate having a first conductivity type, an epitaxial layer having the first conductivity type and disposed on the substrate, a gate insulating layer covering a surface of the first trench, a first gate conductive layer disposed on a sidewall of the first trench, a second gate conductive layer disposed on the other sidewall of the first trench opposite to the sidewall, a doped region having the first conductivity type, a first doped base region having a second conductivity type, a second doped base region having the second conductivity type, a first heavily doped region having the first conductivity type, and a second heavily doped region having the first conductivity type. The epitaxial layer has the first conductivity type, the second gate conductive layer is electrically isolated from the first gate conductive layer, and the doped region is disposed in the epitaxial layer at the bottom of the first trench. The first doped base region is disposed in the epitaxial layer at a side of the first gate conductive layer opposite to the second gate conductive layer, and the second doped base region is disposed in the epitaxial layer at a side of the second gate conductive layer opposite to the first gate conductive layer. The first heavily doped region is disposed in the first doped base region, and the second heavily doped region is disposed in the second doped base region, wherein a doping concentration of the doped region is less than a doping concentration of the first heavily doped region and a doping concentration of the second heavily doped region, and a doping concentration of the doped region is more than a doping concentration of the epitaxial layer.

According to the present invention, a manufacturing method for a bilateral conduction semiconductor is provided. The manufacturing method includes the following steps. First, a substrate and an epitaxial layer disposed on the substrate are provided. The epitaxial layer has a first trench, and the epitaxial layer at two sides of the first trench respectively has at least a first doped base region and at least a second doped base region, wherein the substrate and the epitaxial layer have a first conductivity type, and the first doped base region and the second doped base region have a second conductivity type. Then, a gate insulating layer, a first gate conductive layer, and a second gate conductive layer are formed in the first trench, wherein a second trench is formed between the first gate conductive layer and the second gate conductive layer so as to isolate the first gate conductive layer and the second gate conductive layer and expose a portion of the gate insulating layer. Subsequently, a first ion implantation process is performed to implant a first ion region having the first conductivity type into the epitaxial layer under the second trench. Following that, an insulating layer is formed in the second trench. Then, a second ion implantation process and a first drive-in process are performed to form a first heavily doped region in the first doped base region, to form a second heavily doped region in the second doped base region, and to diffuse the first ion region into a doped region.

The present invention is to implant a doped region under the insulating layer between the gate conductive layers so as to decrease the on-resistance of the bilateral conduction semiconductor device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-sectional diagram illustrating a conventional N-type power MOSFET according to the prior art.

FIG. 2 is a schematic diagram illustrating a conventional bilateral conduction semiconductor device in the prior art.

FIGS. 3-7 are schematic diagrams illustrating a method of manufacturing a bilateral conduction semiconductor device according to a first embodiment of the present invention.

FIG. 8 is a schematic diagram of a top view of the bilateral conduction semiconductor device according to the first embodiment of the present invention.

FIG. 9 is a cross-sectional schematic diagram of the bilateral conduction semiconductor device along line B-B′ of FIG. 8 according to the first embodiment of the present invention.

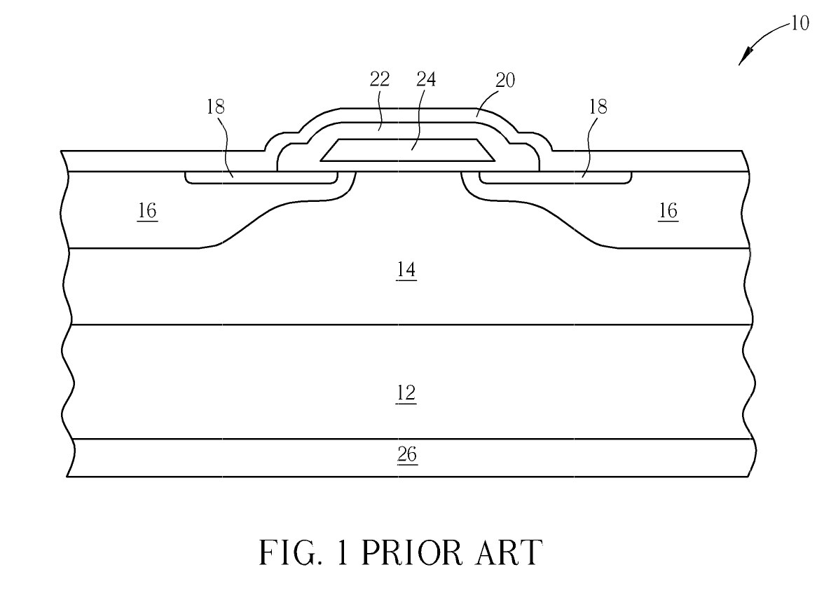

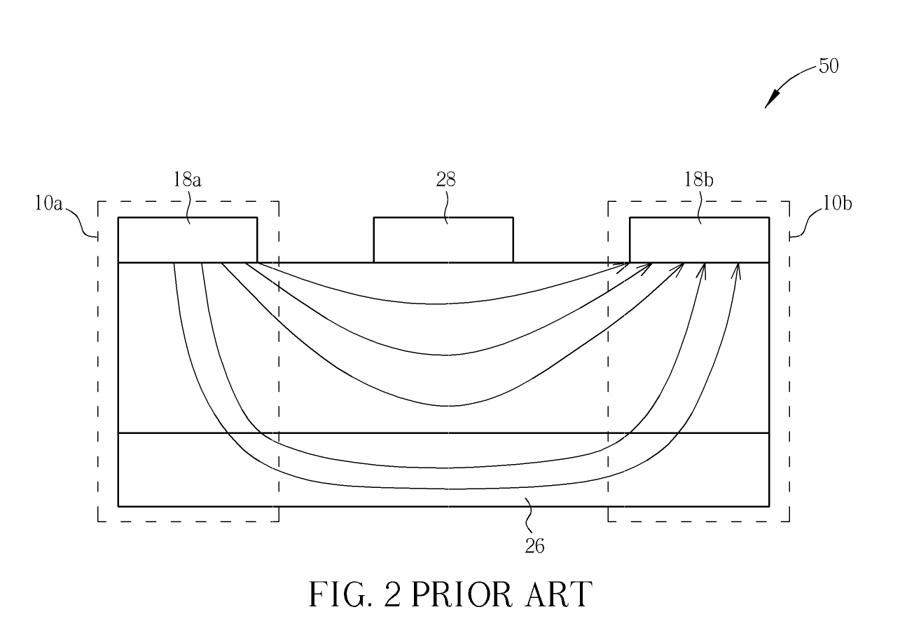

### DETAILED DESCRIPTION

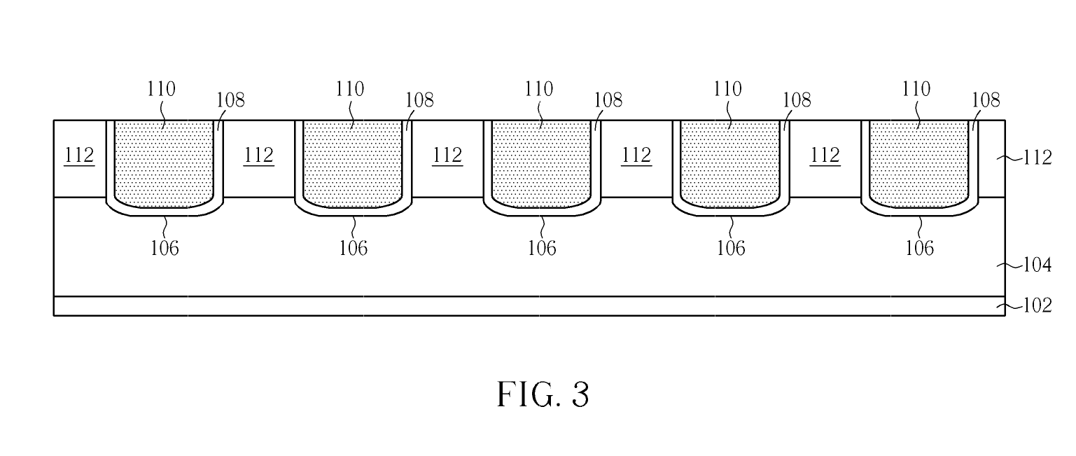

Please refer to FIGS. 3-7. FIGS. 3-7 are schematic diagrams illustrating a method of manufacturing a bilateral conduction semiconductor device according to a first embodiment of the present invention. As shown in FIG. 3, a substrate 102 and an epitaxial layer 104 disposed on the substrate 102 are first provided, and the substrate 102 and the epitaxial layer 104 have a first conductivity type. Then, a lithographic and etching process is performed to form a plurality of first trenches 106 on the epitaxial layer 104. Subsequently, a deposition process is performed to form a first insulating layer (not shown in the figure) and a conductive layer (not shown in the figure) covering the epitaxial layer 104 and each surface of the first trench 106. Following that, a planarization process is performed to remove the first insulating layer and the conductive layer outside of the first trench 106 so as to form a gate insulating layer 108 and a gate conductive layer 110 in each first trench 106. The gate conductive layer 110 is a conductive layer of the first conductivity type, but it is not limited herein. Then, an ion implantation process and a drive-in process are performed to respectively form a doped base region 112 in the epitaxial layer 104 between each two adjacent first trenches 106, and each doped base region 112 has a second conductivity type. In the present embodiment, the first conductivity type is N-type, and the second conductivity type is P-type. But the present invention is not limited to herein, the first conductivity type may be P-type and the second conductivity type may be N-type. It should be noted that the steps for forming the P-type doped base region 112, the gate insulating layer 108, and the gate conductive layer 110 are not limited to the aforementioned method and may be another method described as follows. First, a layer of P-type doped region (not shown in the figure) is formed completely in the N-type epitaxial layer 104. Then, a lithographic and etching process is performed to form a plurality of first trenches 106, and the gate insulating layer 108 and the gate conductive layer 110 are formed in each first trench 106, so that a P-type doped base region 112 is formed in the epitaxial layer 104 between each two adjacent first trenches 106.

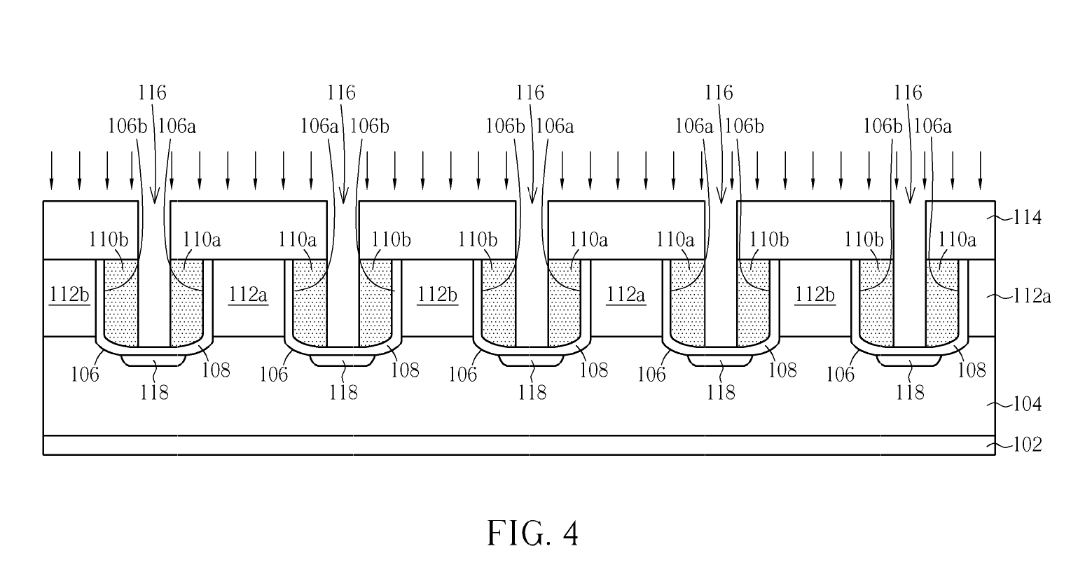

Subsequently, as shown in FIG. 4, a lithographic process is performed to form a patterned photoresist layer 114 on the N-type epitaxial layer 104 so as to expose a portion of the gate conductive layer 110 of each first trench 106. Then, an etching process is performed to remove the exposed gate conductive layer 110 in each first trench 106 so as to form a first gate conductive layer 110a and a second gate conductive layer 110b in each first trench 106 and to expose a portion of the gate insulating layer 108, so that a second trench 116 is formed between the first gate conductive layer 110a and the second gate conductive layer 110b in each first trench 106. Also, the P-type doped base regions 112 may be divided into a plurality of first P-type doped base regions 112a and a plurality of second P-type doped base regions 112b. Each first P-type doped base region 112a and each second P-type doped base region 112b are disposed alternatively in sequence. When one of the P-type doped base regions 112 between any two adjacent first trenches 106 is the first P-type doped base region 112a, each first gate conductive layer 110a in each of the two first trenches 106 is disposed on a sidewall 106a of each of the two first trenches 106 near the first P-type doped base region 112a, and each second gate conductive layer 110b in each of the two first trenches 106 is disposed on the other sidewall 106b of each of the two first trenches 106 opposite to the sidewall 106a. In other words, when one of the P-type doped base regions 112 between any two adjacent first trenches 106 is the second P-type doped base region 112b, each second gate conductive layer 110b in each of the two first trenches 106 is disposed on the sidewall 106b of the first trench 106 near the second P-type doped base region 112b. Then, the same patterned photoresist layer 114 also serves as a mask to perform a first N-type ion implantation process so as to form a first N-type ion region 118 in the N-type epitaxial layer 104 under the second trench 116.

In addition, it should be noted that the steps for forming the gate insulating layer 108, the first gate conductive layer 110a, and the second gate conductive layer 110b in the present invention is not limited to the aforementioned method, and can be the following steps. After the steps of forming a first insulating layer and a conductive layer to cover the N-type epitaxial layer 104 and each surface of the first trenches 106, an etching process, such as a dry etching process, is performed to directly remove the first insulating layer and the conductive layer outside of the first trench 106 and to remove a portion of the conductive layer of each first trench 106 so as to form the gate insulating layer 108 and to form the first gate conductive layer 110a and the second gate conductive layer 110b in each first trench 106.

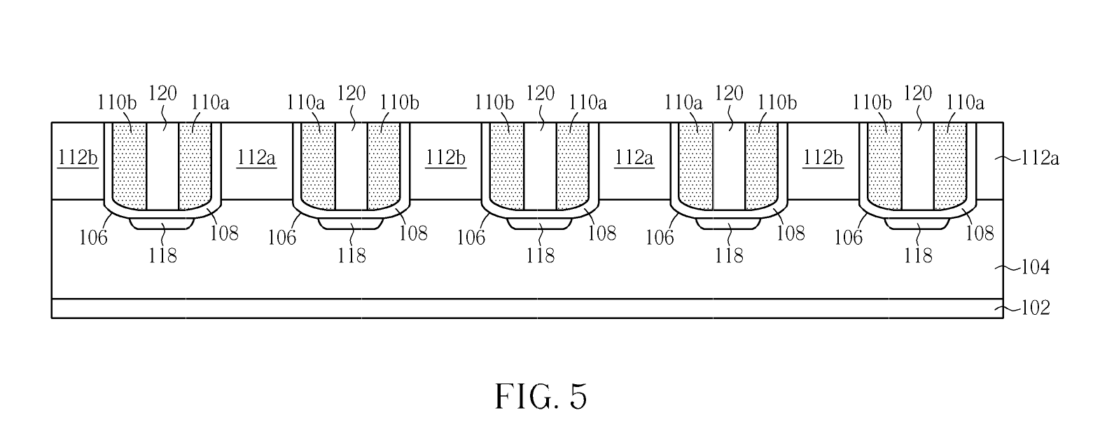

Following that, as shown in FIG. 5, the patterned photoresist layer 114 is removed, and a deposition process is performed to form a second insulating layer (not shown in the figure) on the N-type epitaxial layer 104, and the second trench 116 is filled with the second insulating layer. Then, a planarization process is performed to remove the second insulating layer outside of each second trench 116 so as to form an insulating layer 120 in each second trench 116 for electrically isolating the first gate conductive layer 110a and the second gate conductive layer 110b, wherein the first gate conductive layer 110a may serve as a gate electrode of a first MOSFET of the bilateral conduction semiconductor device, and the second gate conductive layer 110b may serve as a gate electrode of a second MOSFET of the bilateral conduction semiconductor device.

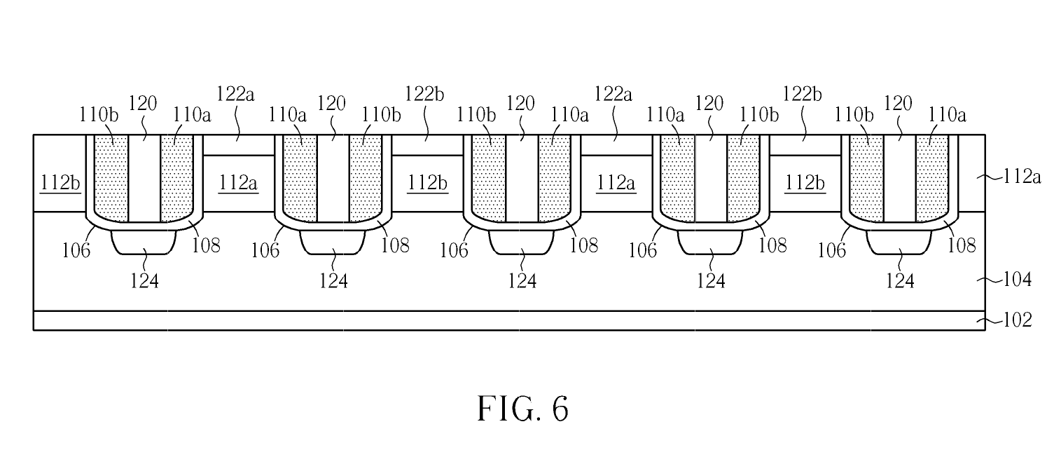

Then, as shown in FIG. 6, another patterned photoresist layer (not shown in the figure) is utilized to cover the most outside of the first P-type doped base region 112a and the second P-type doped base region 112b so as to expose other first P-type doped base regions 112a, other second P-type doped base regions 112b, the first gate conductive layers 110a, and the second gate conductive layers 110b. Subsequently, a second N-type ion implantation process is performed to form a second N-type ion region (not shown in the figure) in each first P-type doped base region 112a and each second P-type doped base region 112b, and each first gate conductive layer 110a and each second gate conductive layer 110b are still N-type conductive layers. Following that, a first drive-in process is performed to respectively diffuse the second N-type ion regions of each first P-type doped base region 112a and each second P-type doped base region 112b into a first N-type heavily doped region 122a and a second N-type heavily doped region 122b, and to diffuse each first N-type ion region 118 under each insulating layer 120 into an N-type doped region 124. Each first N-type heavily doped region 122a may serve as the source electrode of the first MOSFET, and each second N-type heavily doped region 122b may serve as the source electrode of the second MOSFET. Each N-type doped region 124 may serve as the drain electrode of the first MOSFET and the second MSOFET. In addition, a doping concentration of the second N-type ion implantation process is larger than a doping concentration of the first N-type ion implantation process, so that a doping concentration of the first N-type heavily doped region 122a and the second N-type heavily doped region 122b is larger than a doping concentration of the N-type doped region 124. Also, a doping concentration of the N-type doped region 124 is larger than a doping concentration of N-type epitaxial layer 104, and each N-type doped region 124 is disposed in the N-type epitaxial layer 104 under each insulating layer 120 so as to decrease the resistance of the N-type epitaxial layer 104. Moreover, each N-type doped region 124 may laterally extend to the N-type epitaxial layer 104 under each corresponding first gate conductive layer 110a and each corresponding second gate conductive layer 110b by performing the first drive-in process. However, it should be noted that each N-type doped region 124 of the present invention does not extend to be in touch with each first P-type doped base region 112a and each second P-type doped base region 112b respectively at two sides of each first trench 106 so as to avoid the decrease of the area and the thickness of N-type epitaxial layer 104 and the decrease of the voltage-sustaining degree of the bilateral conduction semiconductor device. Also, in the present invention, each N-type doped region 124 is preferably only disposed under each insulating layer 120 and preferably does not extend to the N-type epitaxial layer under each corresponding first gate conductive layer 110a and each corresponding second gate conductive layer 110b. In addition, in the present invention, a second drive-in process may be performed between the first N-type ion implantation process and the second N-type ion implantation process to diffuse the first N-type ion region 118.

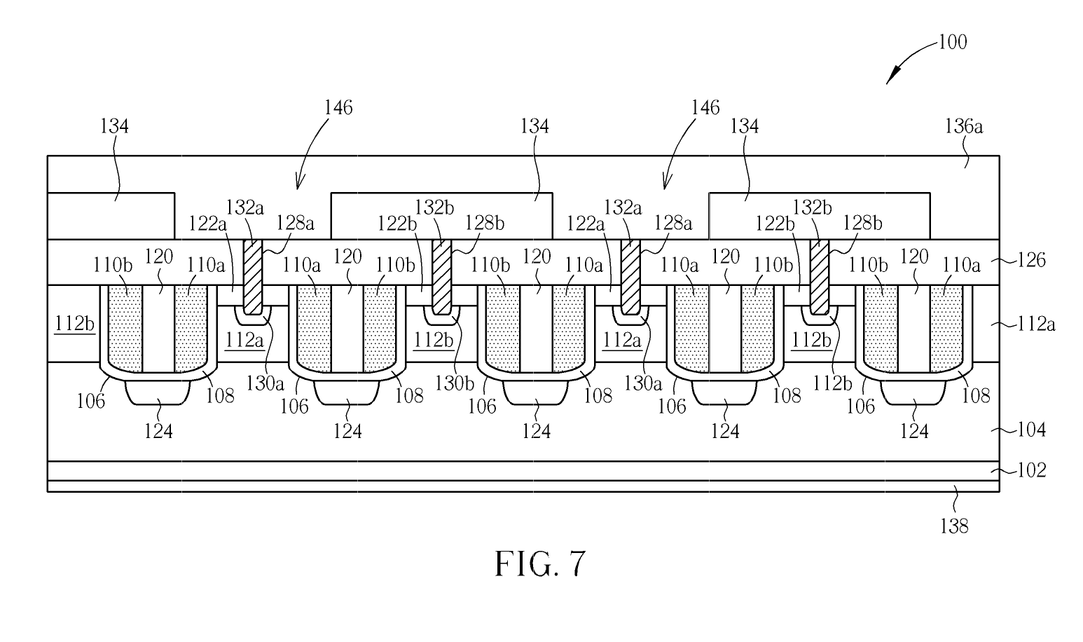

Subsequently, as shown in FIG. 7, a deposition process is performed to cover the N-type epitaxial layer 104 with a first dielectric layer 126. Then, a lithographic and etching process is performed to form a plurality of first contact holes 128a and a plurality of second contact holes 128b in the first dielectric layer 126, wherein the first contact hole 128a punches through the first dielectric layer 126 and the first N-type heavily doped region 122a, and the second contact hole 128b punches through the first dielectric layer 126 and the second N-type heavily doped region 122b. Following that, a P-type ion implantation process and a drive-in process are performed to form a first P-type contact region 130a in each first P-type doped base region 112a and to form a second P-type contact region 130b in each second P-type doped base region 112b through each first contact hole 128a and each second contact hole 128b. Then, a deposition process is performed to form a first contact plug 132a in each first contact hole 128a and to form a second contact plug 132b in each second contact hole 128b, so that each first contact plug 132a is connected to each corresponding first N-type heavily doped region 122a and each corresponding first P-type contact region 130a, and each second contact plug 132b is connected to each corresponding second N-type heavily doped region 122b and each corresponding the second P-type contact region 130b. In addition, in the steps of forming the first contact plug 132a and the second contact plug 132b, a plurality of first gate contact plugs 144a (not shown in FIG. 6) and a plurality of second gate contact plugs 144b (not shown in FIG. 6) are also formed.

Following that, a second dielectric layer 134 is formed on the first dielectric layer 126, and the second dielectric layer 134 has a plurality of apertures 146 respectively exposing a portion of the first contact plug 132a and the first dielectric layer 126 and exposing a portion of the second contact plug 132b, each first gate contact plug 144a, and each second gate contact plug 144b (not shown in FIG. 7). Then, a first source metal layer 136a is formed on the first contact plugs 132a and the second dielectric layer 134, and the first source metal layer 136a is over the first trenches 106, so that the apertures 146 exposing the first contact plug 132a are filled with the first source metal layer 136a for electrically connecting the first contact plugs 132a, and the second dielectric layer 134 electrically isolates the first source metal layer 136a and the second contact plug 132b. Also, a second source metal layer 136b (not shown in FIG. 7) is simultaneously formed on the second contact plug 132b and the second dielectric layer 134, and the second source metal layer 136b is over the first trenches 106, so that the apertures 146 exposing the second contact plug 132b are filled with the second source metal layer 136b for electrically connecting the second contact plugs 132b, and the second dielectric layer 134 electrically isolates the second source metal layer 136b and the second contact plug 132a. Accordingly, each first N-type heavily doped region 122a is electrically connected to the first source metal layer 136a through each first contact plug 132a, and each second N-type heavily doped region 122b is electrically connected to the second source metal layer 136b through each the second contact plug 132b, so that the source electrode of the first MOSFET and the source electrode of the second MOSFET can be electrically connected to the outside, respectively. In addition, in the steps of forming the first source metal layer 136a and the second source metal layer 136b, a first gate metal layer 140a (not shown in FIG. 7) is simultaneously formed on the second dielectric layer 134 and each first gate contact plug 144a, and a second gate metal layer 140b (not shown in FIG. 7) is formed on the second dielectric layer 134 and each second gate contact plug 144b, so that the first gate metal layer 140a is electrically connected to each first gate conductive layer 110a through each first gate contact plug 144a, and the second gate metal layer 140b is electrically connected to the second gate conductive layer 110b through the second gate contact plug 144b. Then, a drain metal layer 138 is formed under the N-type substrate 102. The bilateral conduction semiconductor device 100 of the present invention is therefore finished. Because the drain metal layer 138 is formed under the N-type substrate 102, the time to perform the step of forming the drain metal layer 138 is not limited to the above-mentioned method, and may be another appropriate time, such as before or after the front-side process of the N-type substrate 102.

It should be noted that the present invention implant an N-type doped region 124 under each insulating layer 120 to decrease the resistance of N-type epitaxial layer 104 under the insulating layer 120, so that the current transmitting from the first/second N-type heavily doped region 122a/122b to the N-type epitaxial layer 104 can more easily enter the corresponding N-type epitaxial layer 104 under the second/first gate conductive layer 110b/110a through the N-type doped region 124, and then, can transmit to the second/first N-type heavily doped region 122b/122a. Therefore, it can prevent the current from transmitting toward the N-type substrate 102. Also, the resistance resulted from the N-type epitaxial layer 104 and N-type substrate 102 can be ignored, so that the on-resistance (Rdson) between the drain electrode and the source electrode of the first MOSFET or the on-resistance between the drain electrode and the source electrode of the second MOSFET can be decreased to reduce the on-resistance of the bilateral conduction semiconductor device 100. In the present embodiment, a width of the first MOSFET or the second MOSFET is substantially 1.5 micrometers, and as compared to the conventional MOSFET with a width of 1.05 micrometers, the on-resistance between the drain electrode and the source electrode of the first MOSFET or the second MOSFET of the present embodiment can decrease further about 30%. But the present invention is not limited to this width.

In addition, the present invention is not limited to forming a plurality of first trenches and can only form a first trench, and a first P-type doped base region 112a and a second P-type doped base region 112b are respectively disposed at two sides of the first trench 106. Also, the first gate conductive layer 110a of the first trench 106 is disposed on the sidewall 106a near the first P-type doped base region 112a, and the second gate conductive layer 110b is disposed on the sidewall 106b near the second P-type doped base region 112b.

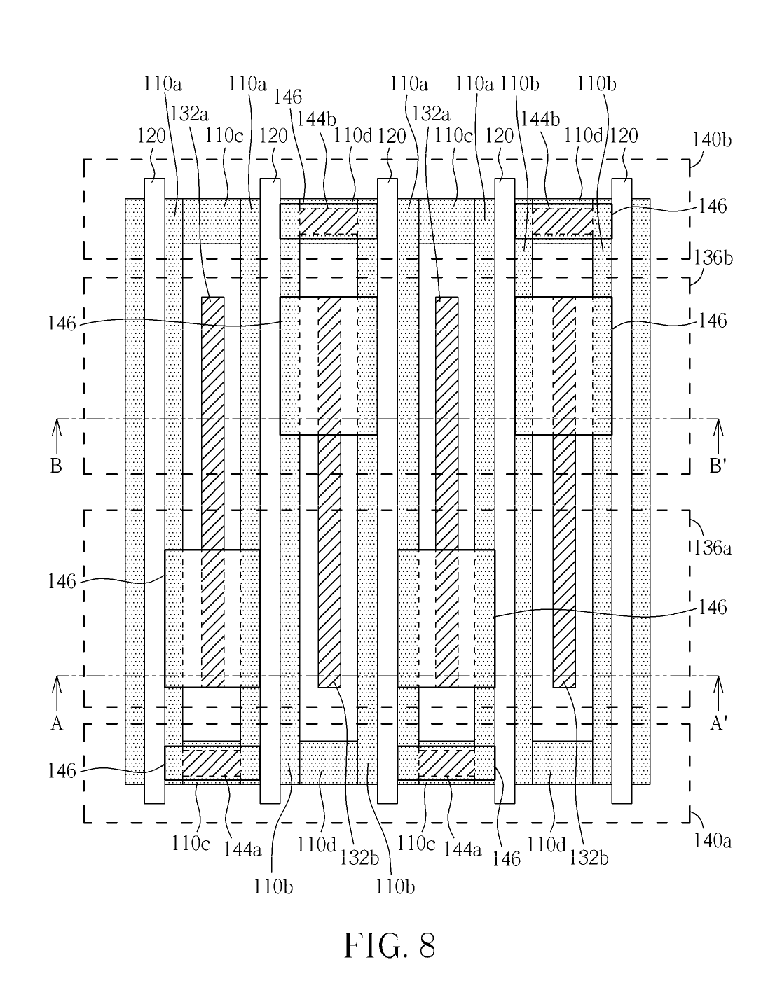

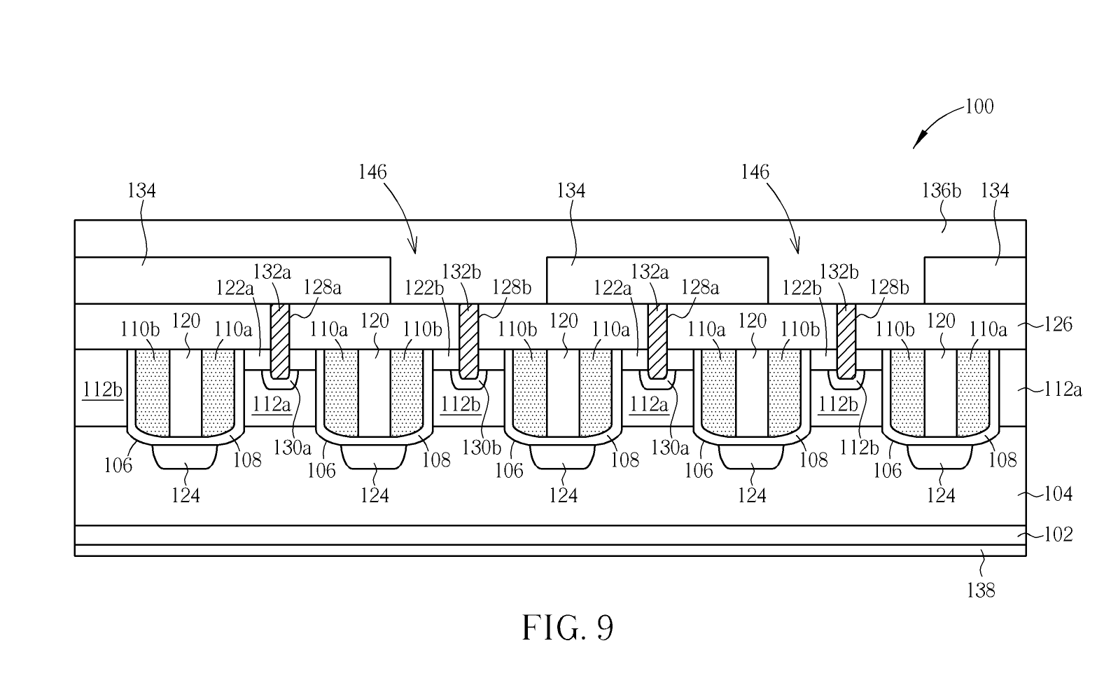

In order to clearly explain the structure of the present invention the bilateral conduction semiconductor device, please refer to FIG. 8 and FIG. 9 in combination with FIG. 7. FIG. 8 is a schematic diagram of a top view of the bilateral conduction semiconductor device according to the first embodiment of the present invention. FIG. 7 is a cross-sectional schematic diagram of the bilateral conduction semiconductor device along line A-A′ of FIG. 8 according to the first embodiment of the present invention, and FIG. 9 is a cross-sectional schematic diagram of the bilateral conduction semiconductor device along line B-B′ of FIG. 8 according to the first embodiment of the present invention. As shown in FIGS. 7-9, the bilateral conduction semiconductor device 100 of the present embodiment further includes a plurality of third gate conductive layers 110c and a plurality of fourth gate conductive layers 110d, wherein the third gate conductive layers 110c between any two adjacent insulating layers 120 are at two edges of the first gate conductive layer 110a and connect with two first gate conductive layers 110a to surround each first contact plug 132a, and the fourth gate conductive layers 110d between any two adjacent insulating layers 120 are at two edges of the second gate conductive layer 110b and connect with two second gate conductive layers 110b to surround each second contact plug 132b. Moreover, each first gate contact plug 144a and each second gate contact plug 144b are disposed in the first dielectric layer 126. Each first gate contact plug 144a is disposed on each third gate conductive layer 110c at the same edge of each first gate conductive layer 110a, and each second gate contact plug 144b is disposed on each fourth gate conductive layer 110d at the other edge of the second gate conductive layer 110b opposite to each first gate contact plug 144a. Also, the first gate metal layer 140a is over each insulating layer 120 and is disposed on each first gate contact plug 144a exposed by the aperture 146 of the second dielectric layer 134 so as to electrically connect to each first gate conductive layer 110a through each first gate contact plug 144a. The second gate metal layer 140b is over each insulating layer 120 and is disposed on each second gate contact plug 144b exposed by the aperture 146 of the second dielectric layer 134 so as to electrically connect to each second gate conductive layer 110b through each second gate contact plug 144b. In addition, the first source metal layer 136a and the second source metal layer 136b are disposed between the first gate metal layer 140a and the second gate metal layer 140b, the first source metal layer 136a is electrically connected to each the first contact plug 132a through the aperture 146 of the second dielectric layer 134, and the second source metal layer 136b is electrically connected to each second contact plug 132b through the aperture 146 of the second dielectric layer 134.

In summary, the present invention utilizes a trench to form two electrically isolated gate conductive layers for respectively serving as the gate electrodes of two MOSFET of the bilateral conduction semiconductor device, and the present invention implant a doped region under the insulating layer between the gate conductive layers so as to decrease the on-resistance between the drain electrode and the source electrode of each MOSFET, to reduce the on-resistance of the bilateral conduction semiconductor device, and to lessen the power consumption of the bilateral conduction semiconductor device.

Those skilled in the art will readily observe that numerous modifications and alterations of the device and method may be made while retaining the teachings of the invention.

What is claimed is:

1. A bilateral conduction semiconductor, comprising:
a substrate, having a first conductivity type;
an epitaxial layer, having the first conductivity type, the epitaxial layer being disposed on the substrate, and the epitaxial layer having a first trench;
a gate insulating layer, covering a surface of the first trench;
a first gate conductive layer, disposed on a sidewall of the first trench;
a second gate conductive layer, disposed on the other sidewall of the first trench opposite to the sidewall, wherein the second gate conductive layer is electrically isolated from the first gate conductive layer;
a doped region, having the first conductivity type, and the doped region being disposed in the epitaxial layer at the bottom of the first trench;
a first doped base region, having a second conductivity type, and the first doped base region being disposed in the epitaxial layer near the first gate conductive layer, wherein the gate insulating layer electrically isolates the first gate conductive layer and the first doped base region;
a second doped base region having the second conductivity type, and the second doped base region being disposed in the epitaxial layer near the second gate conductive layer, wherein the gate insulating layer electrically isolates the second gate conductive layer and the second doped base region;
a first heavily doped region, having the first conductivity type, and the first heavily doped region being disposed in the first doped base region; and
a second heavily doped region, having the first conductivity type, and the second heavily doped region being disposed in the second doped base region, wherein a doping concentration of the doped region is less than a doping concentration of the first heavily doped region and a doping concentration of the second heavily doped region, and a doping concentration of the doped region is more than a doping concentration of the epitaxial layer.

2. The bilateral conduction semiconductor of claim 1, further comprising an insulating layer, disposed between the first gate conductive layer and the second gate conductive layer so as to isolate the first gate conductive layer and the second gate conductive layer.

3. The bilateral conduction semiconductor of claim 2, wherein the doped region is disposed in the epitaxial layer under the insulating layer.

4. The bilateral conduction semiconductor of claim 3, wherein the doped region is laterally extended to the corresponding first gate conductive layer and to the epitaxial layer under the second gate conductive layer, and the doped region is not in contact with the first doped base region and the second doped base region.

5. The bilateral conduction semiconductor of claim 1, further comprising a first source metal layer and a second source metal layer disposed on the epitaxial layer, wherein the first source metal layer is electrically connected to the first heavily doped region, and the second source metal layer is electrically connected to the second heavily doped region.

6. The bilateral conduction semiconductor of claim 5, further comprising a first dielectric layer, wherein the first dielectric layer is disposed between the epitaxial layer and the first source metal layer and between the epitaxial layer and the second source metal layer.

7. The bilateral conduction semiconductor of claim 6, further comprising a first contact plug and a second contact plug disposed in the epitaxial layer, wherein the first contact plug electrically connects the first source metal layer and the first heavily doped region, and the second contact plug electrically connects the second source metal layer and the second heavily doped region.

8. The bilateral conduction semiconductor of claim 7, further comprising a first doped source contact region and a second doped source contact region, wherein the first doped source contact region is disposed between the first contact plug and the first doped base region, and the second doped source contact region is disposed between the second contact plug and the second doped base region.

9. The bilateral conduction semiconductor of claim 7, further comprising a second dielectric layer, wherein the second dielectric layer is disposed between the first contact plug and the second source metal layer, and the second dielectric layer is disposed between the second contact plug and the first source metal layer.

10. The bilateral conduction semiconductor of claim 1, further comprising a drain metal layer, wherein the drain metal layer is disposed under the substrate.

11. The bilateral conduction semiconductor of claim 1, wherein the epitaxial layer further has at least another first trench disposed on a side of the first doped base region opposite to the first trench, the bilateral conduction semiconductor further comprises at least another first gate conductive layer and at least another second gate conductive layer disposed in the another first trench, and the another first gate conductive layer is disposed between the first gate conductive layer and the another second gate conductive layer.

12. The bilateral conduction semiconductor of claim 1, wherein the epitaxial layer has at least another first trench disposed on a side of the second doped base region opposite to the first trench, the bilateral conduction semiconductor further comprises at least another first gate conductive layer and at least another second gate conductive layer disposed in the another first trench, and the another second gate conductive layer is disposed between the second gate conductive layer and the another first gate conductive layer.

13. The bilateral conduction semiconductor of claim 1, wherein the first conductivity type is N-type, and the second conductivity type is P-type.

14. A manufacturing method for a bilateral conduction semiconductor, the manufacturing method comprising the steps of:
providing a substrate and an epitaxial layer disposed on the substrate, the epitaxial layer having a first trench, and the epitaxial layer at two sides of the first trench respectively having at least a first doped base region and at least a second doped base region, wherein the substrate and the epitaxial layer have a first conductivity type, and the first doped base region and the second doped base region have a second conductivity type;
forming a gate insulating layer, a first gate conductive layer, and a second gate conductive layer in the first trench, wherein a second trench is formed between the first gate conductive layer and the second gate conductive layer so as to isolate the first gate conductive layer and the second gate conductive layer and expose a portion of the gate insulating layer;
performing a first ion implantation process to implant a first ion region having the first conductivity type into the epitaxial layer under the second trench;
forming an insulating layer in the second trench; and
performing a second ion implantation process and a first drive-in process to form a first heavily doped region in the first doped base region, to form a second heavily doped region in the second doped base region, and to diffuse the first ion region into a doped region.

15. The manufacturing method of claim 14, wherein a mask used for forming the second trench is the same as a mask used for performing the first ion implantation process.

16. The manufacturing method of claim 14, further comprising a second drive-in process for diffusing the first ion region, wherein the second drive-in process is performed between the first ion implantation process and the second ion implantation process.

17. The manufacturing method of claim 14, further comprising a drain metal layer formed under the substrate.

18. The manufacturing method of claim 14, wherein the epitaxial layer has at least another first trench disposed on a side of the first doped base region opposite to the first trench, in the steps for forming the first gate conductive layer and the second gate conductive layer, the manufacturing method further comprises forming at least another first gate conductive layer and at least another second gate conductive layer in the another first trench, and the another first gate conductive layer is disposed between the first gate conductive layer and the another second gate conductive layer.

19. The manufacturing method of claim 14, wherein the epitaxial layer has at least another first trench disposed on a side of the second doped base region opposite to the first trench, in the steps for forming the first gate conductive layer and the second gate conductive layer, the manufacturing method further comprises forming at least another first gate conductive layer and at least another second gate conductive layer in the another first trench, and the another second gate conductive layer is disposed between the second gate conductive layer and the another first gate conductive layer.
